(19) United States
(12) Patent Application Publication
(10) Pub. No.: US 2026/0313875 A1
(43) Pub. Date: Oct. 8, 2026

(54) MICROELECTRONIC DEVICES AND RELATED MEMORY DEVICES

(71) Applicant: Micron Technology, Inc., Boise, ID (US)

(72) Inventors: Kamal M. Karda, Boise, ID (US); Eric S. Carman, San Francisco, CA (US); Duane R. Mills, Shingle Springs, CA (US); David A. Daycock, Boise, ID (US); Benben Li, Boise, ID (US); Muralikrishnan Balakrishnan, Boise, ID (US)

(21) Appl. No.: 19/561,273

(22) Filed: Mar. 9, 2026

Related U.S. Application Data
(60) Provisional application No. 63/783,114, filed on Apr. 3, 2025.

(51) Int. Cl. H10B 12/00; G11C 11/408

(52) U.S. Cl. CPC H10B 12/30; G11C 11/4085; H10B 12/50

(57) ABSTRACT

A microelectronic device includes local word line (LWL) structures, memory cells, sub-word line driver (SWD) devices, and a global word line (GWL) structure. The LWL structures are vertically stacked relative to one another. The memory cells are vertically stacked relative to one another within a vertical span of the LWL structures, and are operatively connected to different ones of the LWL structures than one another. The SWD devices are vertically stacked relative to one another within the vertical span of the LWL structures, and are individually operatively connected to a respective one of the LWL structures. The GWL structure continuously vertically extending across and is operatively connected to the SWD devices. Related memory devices and electronic systems are also described.

### CROSS-REFERENCE TO RELATED APPLICATIONS

This application claims the benefit under 35 U.S.C. § 119(e) of U.S. Provisional Patent Application Ser. No. 63/783,114, filed Apr. 3, 2025, the disclosure of which is hereby incorporated herein in its entirety by this reference.

### TECHNICAL FIELD

This disclosure, in various embodiments, relates generally to the field of microelectronic device design and fabrication. More specifically, the disclosure relates to microelectronic devices including global word lines, local word lines, and sub-word line driver devices, and to related memory devices and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, volatile memory devices, such as dynamic random-access memory (DRAM) devices; and non-volatile memory devices such as NAND Flash memory devices. A typical memory cell of a DRAM device includes one access device, such as a transistor, and one storage node device, such as a capacitor. Modern applications for semiconductor devices can employ significant quantities of memory cells, arranged in memory arrays exhibiting rows and columns of the memory cells. The memory cells may be electrically accessed through digit lines (e.g., bit lines, data lines) and word lines (e.g., access lines) arranged along the rows and columns of the memory cells of the memory arrays. Memory arrays can be two-dimensional (2D) so as to exhibit a single deck (e.g., a single tier, a single level) of the memory cells, or can be three-dimensional (3D) so as to exhibit multiple decks (e.g., multiple levels, multiple tiers) of the memory cells.

Control logic devices within a base control logic structure underlying a memory array of a memory device have been used to control operations (e.g., access operations, read operations, write operations) of the memory cells of the memory device. An assembly of the control logic devices may be provided in electrical communication with the memory cells of the memory array by way of routing and interconnect structures. However, the quantities, dimensions, and arrangements of the different control logic devices employed within the base control logic structure can also undesirably impede reductions to the size (e.g., horizontal footprint) of the memory device, and/or improvements in the performance (e.g., faster memory cell ON/OFF speed, lower threshold switching voltage requirements, faster data transfer rates, lower power consumption) of the memory device. Furthermore, as the density and complexity of the memory array have increased, so has the complexity of the control logic devices. In some instances, the control logic devices consume more real estate than the memory devices, reducing the memory density of the memory device.

### BRIEF DESCRIPTION OF THE DRAWINGS

FIG. 1 shows a simplified, partial-cutaway perspective view of a microelectronic device, in accordance with some embodiments of the disclosure.

FIG. 2A shows a simplified, partial-cutaway perspective view of a portion A (identified with a dashed box in FIG. 1) of the microelectronic device shown in FIG. 1, in accordance with some embodiments of the disclosure. FIG. 2B shows a simplified, partial vertical cross-sectional view, in a ZY-plane, of a section B (identified with a dashed line B-B shown in FIG. 1) of the microelectronic device collectively shown in FIGS. 1 and 2A. FIG. 2C shows a simplified, partial-cutaway perspective view of a further portion of the microelectronic device collectively shown in FIGS. 1, 2A, and 2B.

FIG. 3A shows a simplified, partial-cutaway perspective view of a portion A (identified with a dashed box in FIG. 1) of the microelectronic device shown in FIG. 1, in accordance with some additional embodiments of the disclosure. FIG. 3B is a simplified, partial vertical cross-sectional view, in a ZY-plane, of a section B (identified with a dashed line B-B shown in FIG. 1) of the microelectronic device collectively shown in FIGS. 1 and 3A. FIG. 3C shows a simplified, partial vertical cross-sectional view, in a ZX-plane, of an additional portion of the microelectronic device collectively shown in FIGS. 1, 3A, and 3B.

FIG. 4 is a block diagram of an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device, such as 3D DRAM memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, the term “memory device” means and includes microelectronic devices exhibiting memory functionality, but not necessarily limited to memory functionality. Stated another way, and by way of example only, the term “memory device” means and includes not only conventional memory (e.g., conventional volatile memory, such as conventional DRAM; conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., materials, structures, regions, circuitry, devices) described as “neighboring” one another means and includes features of the disclosed identity (or identities) that are located most proximate (e.g., closest to) one another. Additional features (e.g., additional material, additional structures, additional regions, additional circuitry, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms following “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively doped polysilicon, conductively doped germanium (Ge), conductively doped silicon germanium (SiGe)). In addition, a “conductive structure” means and includes a structure formed of and including a conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). In addition, an “insulative structure” means and includes a structure formed of and including an insulative material.

As used herein, “semiconductor material” and “semiconductive material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

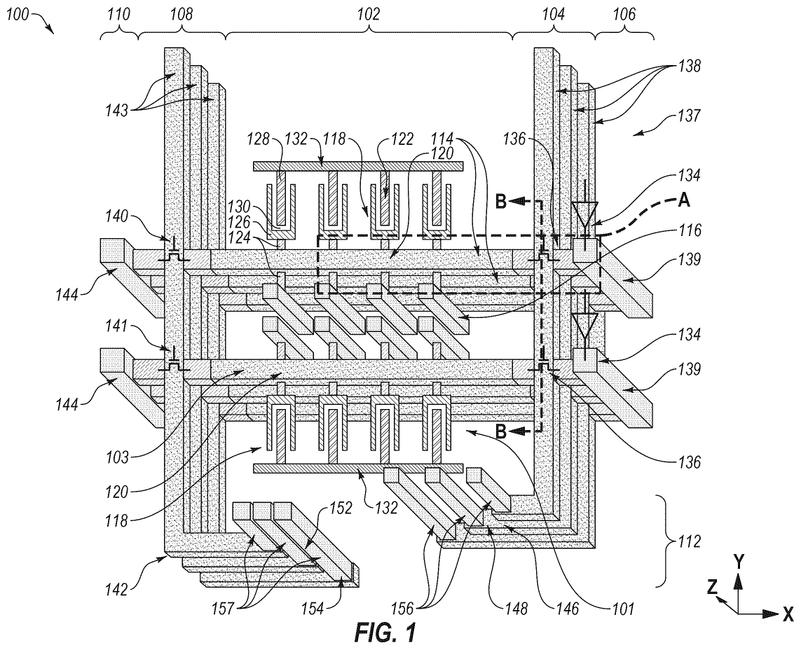

FIG. 1 shows a simplified, partial-cutaway perspective view of a microelectronic device 100 (e.g., memory device, such as 3D DRAM device), in accordance with some embodiments of the disclosure. The microelectronic device 100 may include at least one memory array region 102; at least one word line select (WLSEL) region 104 horizontally neighboring the memory array region 102 in an X-direction (e.g., a first horizontal direction); and at least one global word line (GWL) region 106 horizontally neighboring the WLSEL region 104 in the X-direction. In addition, the microelectronic device 100 may further include at least one word line idle (WLIDLE) region 108 horizontally neighboring the memory array region 102 in the X-direction (horizontally opposite the WLSEL region 104); at least one additional GWL region 110 horizontally neighboring the WLIDLE region 108 in the X-direction; and at least one staircase region 112 (also referred to herein as a “select line contact region”) horizontally neighboring the memory array region 102 in a Y-direction (e.g., a second horizontal direction) orthogonal to the X-direction. The memory array region 102 may be horizontally interposed between the WLSEL region 104 and the WLIDLE region 108 in the X-direction; and each of the WLSEL region 104 and the WLIDLE region 108 may be horizontally interposed between the GWL region 106 and the additional GWL region 110 in the X-direction. As shown in FIG. 1, the WLSEL region 104 may be horizontally interposed between the memory array region 102 and the GWL region 106 in the X-direction; and the WLIDLE region 108 may be horizontally interposed between the memory array region 102 and the additional GWL region 110 in the X-direction. The memory array region 102, the WLSEL region 104, the GWL region 106, the WLIDLE region 108, the additional GWL region 110, and the staircase region 112 of the microelectronic device 100 are described in further detail below, as are additional features of the microelectronic device 100.

The memory array region 102 may include vertical (e.g., in the Z-direction; into and out of the page in the view of FIG. 1) stacks of volatile memory cells 118. An individual vertical stack of the volatile memory cells 118 includes a vertical stack of access devices 120, and a vertical stack of storage node devices 122 horizontally neighboring (e.g., in the Y-direction) and coupled to the vertical stack of access devices 120. As described in further detail below, for an individual vertical stack of the volatile memory cells 118, each of the volatile memory cells 118 thereof may include one of the access devices 120 horizontally neighboring (e.g., in the Y-direction) and coupled to one of the storage node devices 122. Although FIG. 1 illustrates the memory array region 102 as including eight (8) vertical stacks of the volatile memory cells 118, the disclosure is not so limited. For example, the memory array region 102 may include greater than eight (8) (e.g., ten (10), twelve (12), sixteen (16), twenty (20), more than twenty (20)) vertical stacks of the volatile memory cells 118, or may include less than eight (8) vertical stacks of the volatile memory cells 118.

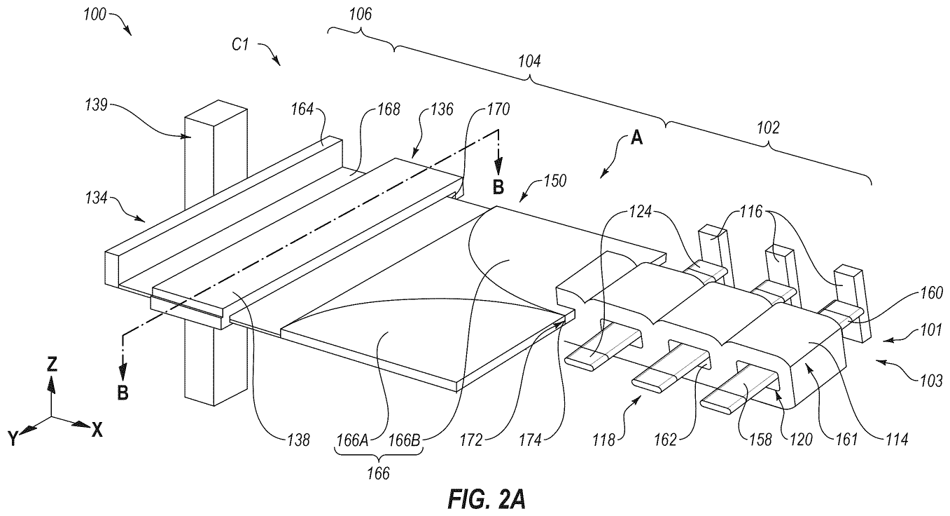

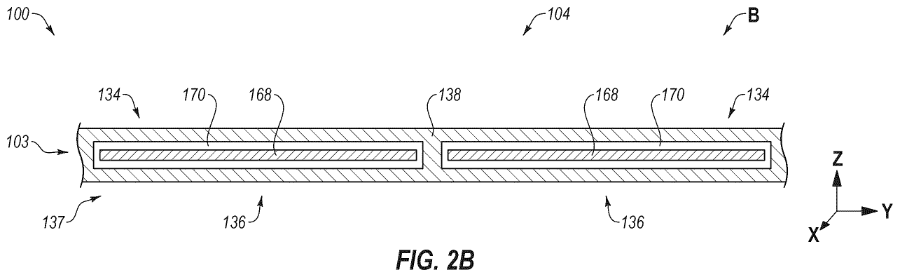

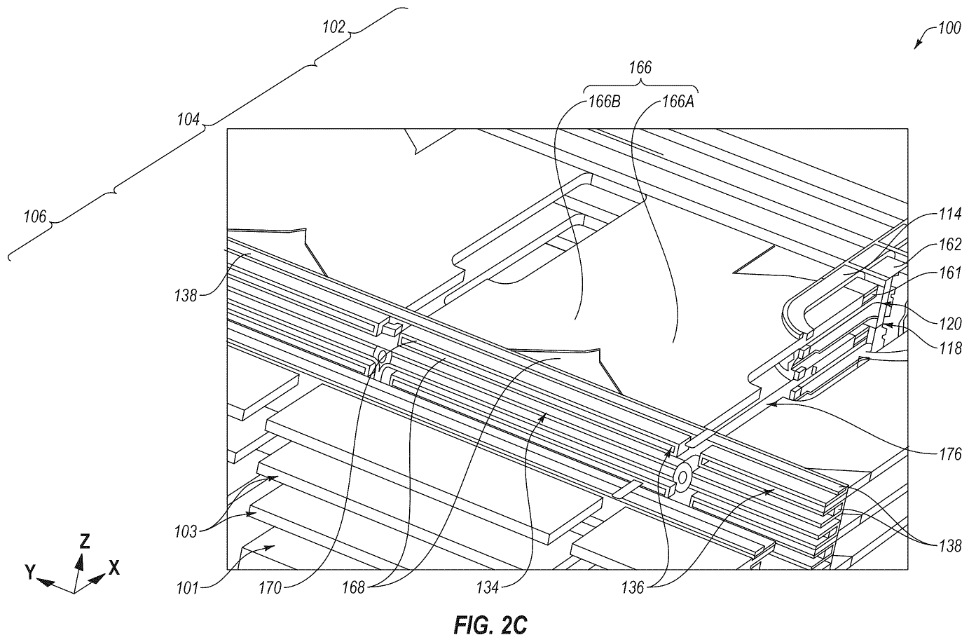

The memory array region 102 further includes stack structures 101 operatively associated with the vertical stacks of the volatile memory cells 118. The stack structures 101 may individually include local word line (LWL) tiers 103 having LWL structures 114 individually operably connected to access devices 120 of different vertical stacks of the access devices 120 of different vertical stacks of the volatile memory cells 118. The LWL tiers 103 (and, hence, the LWL structures 114) of an individual stack structure 101 may be vertically stacked relative to one another in the Z-direction, and may horizontally overlap one another in each of the X-direction and the Y-direction. The LWL structures 114 are also referred to herein as “first conductive lines,” “local word lines,” or “gate electrode structures.” Within an individual stack structure 101, the LWL structures 114 may be spaced vertically apart from one another by one or more insulative materials. The LWL structures 114 of an individual stack structure 101 may individually be configured to provide sufficient voltage to a channel region (described in further detail below with reference to FIG. 2A) of a semiconductor structure 124 of an individual access device 120 of an individual volatile memory cell 118 to electrically connect the storage node device 122 of the volatile memory cell 118 to, for example, a conductive pillar structure 116 (e.g., digit line (DL) pillar structure, DL contact pillar structure) coupled to the access device 120. An individual stack structure 101 may intersect a group of the vertical stacks of the volatile memory cells 118, such as a group of the vertical stacks of the access devices 120 of the group of the vertical stacks of the volatile memory cells 118.

Still referring to FIG. 1, an individual stack structure 101, including the LWL structures 114 within the LWL tiers 103 thereof, horizontally overlaps multiple vertical stacks of the access devices 120 in the Y-direction, and horizontally extends through the multiple vertical stacks of the access devices 120 in the X-direction. An individual stack structure 101 may horizontally extend, in the X-direction, from the WLSEL region 104, through the memory array region 102, and to WLIDLE region 108. An individual LWL structure 114 within an individual LWL tier 103 of an individual stack structure 101 may be coupled to different devices within the WLSEL region 104 and the WLIDLE region 108, as described in further detail below. As shown in FIG. 1, memory array region 102 of the microelectronic device 100 may include at least two (2) of the stack structures 101 horizontally extending in parallel with one another in the X-direction from the WLSEL region 104, through the memory array region 102, and to WLIDLE region 108.

The LWL structures 114 within the LWL tiers 103 of an individual stack structure 101 may respectively be operably connected to one or more vertically neighboring (e.g., in the Z-direction) access devices 120. The channel region of the semiconductor structure 124 of an individual access device 120 of an individual volatile memory cell 118 may be located vertically between (e.g., in the Z-direction) portions of an individual LWL structure 114, as described in further detail below with reference to FIG. 2A. In some embodiments, the access devices 120 are respectively located within a vertical span of an individual LWL structure 114 in the Z-direction. An individual LWL structure 114 may be shared by multiple of the access devices 120 vertically overlapping an individual LWL tier 103 of an individual stack structure 101. Different portions of an individual LWL structure 114 may serve as gates (e.g., gate electrodes) for different access devices 120 horizontally (e.g., in the X-direction and in the Y-direction) and vertically (e.g., in the Z-direction) overlapping the LWL structure 114. As described in further detail below with reference to FIG. 2A, in some embodiments, a portion of an individual LWL structure 114 substantially surrounds four (4) surfaces (e.g., a top surface, a bottom surface, a first side surface, a second side surface) of the semiconductor structure 124 of an individual access device 120 within a horizontal area of a channel region of the access device 120. Thus, the access devices 120 of the volatile memory cells 118 within the memory array region 102 of the microelectronic device 100 may be considered to be Gate-All-Around (GAA) access devices.

Although FIG. 1 illustrates that the LWL structures 114 within the LWL tiers 103 of an individual stack structure 101 individually intersect and form portions (e.g., gates) of four (4) vertical stacks of the volatile memory cells 118, the disclosure is not so limited. In additional embodiments, the LWL structures 114 of an individual stack structure 101 respectively intersect and form portions of fewer than four (4) vertical stacks of the volatile memory cells 118. In further embodiments, the LWL structures 114 of an individual stack structure 101 respectively intersect and form portions of more than four (4) vertical stacks of the volatile memory cells 118, such as six (6) vertical stacks of the volatile memory cells 118, eight (8) vertical stacks of the volatile memory cells 118, ten (10) vertical stacks of the volatile memory cells 118, twelve (12) vertical stacks of the volatile memory cells 118, sixteen (16) vertical stacks of the volatile memory cells 118, or twenty (20) or more vertical stacks of the volatile memory cells 118.

The LWL structures 114 may individually be formed of and include conductive material, such as, for example, one or more of at least one metal (e.g., one or more of W, Ti, Ni, Pt, Rh, Ru, Al, Cu, Mo, Ir, Ag, Au), at least one alloy, at least one metal-containing material (e.g., at least one metal nitride, such as one or more of titanium nitride (TiN), tantalum nitride (TaN), tungsten nitride (WN), and titanium aluminum nitride (TiAlN); at least one metal silicide; at least one metal carbide; at least one conductive metal oxide, such as one or more of iridium oxide (IrOₓ) and ruthenium oxide (RuOₓ)), alloys thereof, at least one conductively doped semiconductor material (e.g., conductively doped Si, conductively doped Ge, conductively doped SiGe). In some embodiments, the LWL structures 114 are individually formed of and include one or more of W, Ti, Ru, Mo, and TiN. In other embodiments, the LWL structures 114 are individually formed of and include Cu.

With continued reference to FIG. 1, the conductive pillar structures 116 within the memory array region 102 may respectively vertically extend (e.g., in the Z-direction) across entire vertical spans of the stack structures 101. The conductive pillar structures 116 may be employed as vertically extending DL structures or vertically extending DL contact structures within the microelectronic device 100. The conductive pillar structures 116 may respectively be coupled to a vertical stack of the access devices 120 within the memory array region 102 to facilitate operation of the volatile memory cells 118 of a vertical stack of the volatile memory cells 118 that includes the vertical stack of the access devices 120. Each conductive pillar structure 116 vertically extends across (e.g., in the Z-direction), and horizontally neighbors (e.g., in the Y-direction), and contacts with the access devices 120 of an individual vertical stack of the volatile memory cells 118. In some embodiments, each conductive pillar structure 116 contacts the semiconductor structure 124 of respective ones of the access devices 120 of an individual vertical stack of the access devices 120 forming a portion of an individual vertical stack of the volatile memory cells 118.

A quantity of the conductive pillar structures 116 within the memory array region 102 may correspond to a quantity of the vertical stacks of the volatile memory cells 118 within the memory array region 102. Each of the vertical stacks of the volatile memory cells 118 may include one (1) of the conductive pillar structures 116 operatively associated therewith. An individual conductive pillar structure 116 may horizontally neighbor an individual vertical stack of the volatile memory cells 118 in the Y-direction, may horizontally overlap the vertical stack of the volatile memory cells 118 in the X-direction, and may continuously vertically extend across an entire vertical span of the vertical stack of the volatile memory cells 118 in the Z-direction. Although FIG. 1 illustrates the memory array region 102 of the microelectronic device 100 as including eight (8) conductive pillar structures 116 therein (e.g., one for each of eight (8) vertical stacks of the volatile memory cells 118), the disclosure is not so limited. For example, at least partially depending on a quantity of vertical stacks of the volatile memory cells 118 within the memory array region 102, the memory array region 102 may include greater than eight (8) (e.g., ten (10), twelve (12), sixteen (16), twenty (20), more than twenty (20)) of the conductive pillar structures 116, or may include less than eight (8) of the conductive pillar structures 116.

The conductive pillar structures 116 may individually be formed of and include conductive material, such as, for example, one or more of at least one metal (e.g., one or more of W, Ti, Ni, Pt, Rh, Ru, Al, Cu, Mo, Ir, Ag, Au), at least one alloy, at least one metal-containing material (e.g., at least one metal nitride, such as one or more of TiN, TaN, WN, and TiAlN); at least one metal silicide; at least one metal carbide; at least one conductive metal oxide (such as one or more of IrOₓ and RuOₓ), alloys thereof, at least one conductively doped semiconductor material (e.g., conductively doped Si, conductively doped Ge, conductively doped SiGe). In some embodiments, the conductive pillar structures 116 are individually formed of and include one or more of W, Ti, Ru, Mo, and TiN.

Still referring to FIG. 1, for an individual vertical stack of the volatile memory cells 118, the storage node devices 122 of the volatile memory cells 118 may horizontally neighbor the access devices 120 of the volatile memory cells 118 in the Y-direction, may horizontally overlap the access devices 120 of the volatile memory cells 118 in the X-direction, and may vertically overlap the access devices 120 in the Z-direction. In some embodiments, the storage node devices 122 of the volatile memory cells 118 are capacitors. For example, the storage node devices 122 may respectively include a first electrode 126 (also referred to herein as a “a first electrode plate,” or a “first node”), a second electrode 128 (also referred to herein as a “a second electrode plate,” or a “second node”), and dielectric material 130 between the first electrode 126 and the second electrode 128. The first electrode 126 may be formed of and include a first conductive material, the second electrode 128 may be formed of and include a second conductive material, and the dielectric material 130 may be formed of and include insulative material. In some embodiments, the first electrode 126 of an individual storage node device 122 is in contact (e.g., electrical contact, physical contact) with an individual access device 120 of the volatile memory cell 118. For example, the first electrode 126 of the storage node device 122 may contact (e.g., electrically contact, physically contact) the semiconductor structure 124 of the access device 120. The first electrode 126 of the storage node device 122 may horizontally neighbor the access device 120 in the Y-direction, may at least partially horizontally overlap the access device 120 in the X-direction, and may at least partially vertically overlap the access device 120 in the Z-direction.

In some embodiments, the volatile memory cells 118 within the memory array region 102 of the microelectronic device 100 are DRAM cells. However, the disclosure is not so limited and in other embodiments, the storage node devices 122 of the volatile memory cells 118 are configured for other types of volatile memory, such as, for example, phase change memory (PCM), resistance random-access memory (RRAM), or conductive-bridging random-access memory (conductive bridging RAM).

With continued reference to FIG. 1, in some embodiments, the memory array region 102 of the microelectronic device 100 further includes conductive plate structures 132 operatively connected to the vertical stacks of the volatile memory cells 118. An individual conductive plate structure 132 may horizontally extend in the X-direction, and may be shared by a group (e.g., multiple) of vertical stacks of the storage node devices 122 of a group (e.g., multiple) of the vertical stacks of the volatile memory cells 118. The conductive plate structure 132 may be coupled to the storage node devices 122 of the group of vertical stacks of the storage node devices 122 of the group of the vertical stacks of the volatile memory cells 118. For example, in embodiments wherein the storage node devices 122 comprise capacitors, the second electrode 128 of respective ones of the storage node devices 122 of respective ones of the group of the vertical stacks of the volatile memory cells 118 may be coupled to an individual conductive plate structure 132.

The memory array region 102 may include at least two (2) of the conductive plate structures 132 horizontally extending in parallel with one another in the X-direction. Each of the at least two (2) of the conductive plate structures 132 may extend across and between the storage node devices 122 of multiple vertical stacks of the volatile memory cells 118. As depicted in FIG. 1, in some embodiments, each of the conductive plate structures 132 extending across and between the storage node devices 122 of four (4) vertical stacks of the volatile memory cells 118. However, the disclosure is not so limited. In additional embodiments, the memory array region 102 may include a different quantity (e.g., more than two (2)) of the conductive plate structures 132, and/or an individual conductive plate structure 132 within the memory array region 102 may be operatively associated with a different quantity (e.g., fewer than four (4); more than four (4), such as six (6), eight (8), ten (10), twelve (12), sixteen (16), twenty (20), or more) of vertical stacks of the volatile memory cells 118.

Still referring to FIG. 1, within the WLSEL region 104 of the microelectronic device 100 includes sub-word line driver (SWD) devices 134 (also referred to herein as “LWL select devices”). The SWD devices 134 may respectively be positioned within a vertical span (e.g., a vertical extent) of the LWL tiers 103 (and the LWL structures 114 thereof) of the stack structures 101, and, hence, may be considered and are also referred to herein as “in-tier” SWD (ITSWD) devices 134 (or as “in-tier LWL select devices”). The SWD devices 134 within the WLSEL region 104 of the microelectronic device 100 may be horizontally oriented orthogonal (e.g., perpendicular) to the access devices 120 within the memory array region 102 of the microelectronic device 100. Various configurations for respective ones of the SWD devices 134 are described in further detail below. The SWD devices 134 within the WLSEL region 104 vertically overlap (e.g., in the Z-direction) and are operatively associated with the LWL structures 114 within the LWL tiers 103 of the stack structures 101 (and, hence, the vertical stacks of the volatile memory cells 118) within the memory array region 102 of the microelectronic device 100. The SWD devices 134 may be substantially vertically confined within vertical extents of the LWL tiers 103 of the stack structures 101, such that the SWD devices 134 are not substantially vertically offset from the LWL tiers 103 of the stack structures 101.

The WLSEL region 104 of the microelectronic device 100 may include multiple vertical stacks 136 of the SWD devices 134. Each of the stack structures 101 within the memory array region 102 may include one (1) of the vertical stacks 136 of the SWD devices 134 operatively associated therewith. As a non-limiting example, as shown in FIG. 1, if the memory array region 102 includes two (2) of the stack structures 101, the WLSEL region 104 may include two (2) vertical stacks 136 of the SWD devices 134. One (1) of the two (2) vertical stacks 136 of the SWD devices 134 may be operatively associated with one (1) of the two (2) of the stack structures 101 (and, hence, one (1) group of vertical stacks of the volatile memory cells 118 operatively connected to the LWL structures 114 of the one (1) of the two (2) of the stack structures 101); and one (1) other of the two (2) vertical stacks 136 of the SWD devices 134 may be operatively associated with one (1) other of the two (2) of the stack structures 101 (and, hence, one (1) other group of vertical stacks of the volatile memory cells 118 operatively connected to the LWL structures 114 of the one (1) other of the two (2) of the stack structures 101). For an individual stack structure 101, an individual vertical stack 136 of the SWD devices 134 operatively associated with the stack structure 101 may vertically overlap the LWL tiers 103 of the stack structure 101 in the Z-direction, may be horizontally offset from the stack structure 101 in the X-direction, and may horizontally overlap the stack structure 101 in the Y-direction. Although FIG. 1 illustrates the WLSEL region 104 of the microelectronic device 100 as including two (2) vertical stacks 136 of the SWD devices 134 therein (e.g., one (1) for each of two (2) stack structures 101), the disclosure is not so limited. For example, at least partially depending on a quantity of the stack structures 101 within the memory array region 102, the WLSEL region 104 may include greater than two (2) vertical stacks 136 of the SWD devices 134, or may include less than two (2) vertical stacks 136 of the SWD devices 134.

The vertical stacks 136 of the SWD devices 134 may be horizontally offset from a vertical stack of the volatile memory cells 118 operatively associated therewith and relatively horizontally closest thereto. For example, a horizontal distance between an individual vertical stack 136 of the SWD devices 134 and a vertical stack of the storage node devices 122 of a vertical stack of the volatile memory cells 118 operatively associated with and relatively horizontally closest thereto may be greater than or equal to about 40 nanometers (nm), such as within a range of from about 40 nm to about 1 micrometer (1 μm), such as from about 40 nm to about 600 nm, or from about 100 nm to about 600 nm. The horizontal distance between the vertical stack 136 of the SWD devices 134 and the vertical stack of the storage node devices 122 relatively horizontally closest thereto may avoid undesirable interferences between the vertical stack 136 of the SWD devices 134 and the vertical stack of the storage node devices 122 during use and operation of the microelectronic device 100.

Within an individual vertical stack 136 of the SWD devices 134, the SWD devices 134 may be vertically offset from one another in the Z-direction, and may horizontally overlap one another in each of the X-direction and the Y-direction. In addition, an individual vertical stack 136 of the SWD devices 134 may include a quantity of the SWD devices 134 sufficient to facilitate desirable electrical communication between the LWL structures 114 of an individual stack structure 101 operatively associated with the vertical stack 136 of SWD devices 134 and a GWL structure 139 within the GWL region 106 of the microelectronic device 100. For example, a quantity of SWD devices 134 included within an individual vertical stack 136 of the SWD devices 134 may be substantially equal to a quantity of LWL structures 114 included within the LWL tiers 103 of an individual stack structure 101 operatively associated with the vertical stack 136 of the SWD devices 134. For example, as shown in FIG. 1, if an individual stack structure 101 includes three (3) LWL structures 114 (e.g., within three (3) LWL tiers 103 of the stack structure 101), the vertical stack 136 of the SWD devices 134 operatively associated with the stack structure 101 may include three (3) of the SWD devices 134. Each of the LWL structures 114 of an individual stack structure 101 may be coupled to a respective one (1) of the SWD devices 134 of an individual vertical stack 136 of the SWD devices 134 vertically overlapping (e.g., in the Z-direction) and horizontally overlapping (e.g., in the Y-direction) the stack structure 101. For an individual LWL structure 114 of an individual stack structure 101, the SWD device 134 of a respective vertical stack 136 of the SWD devices 134 operativity associated with the stack structure 101 may be positioned with a vertical span of the LWL tier 103 including the LWL structure 114. For an individual LWL structure 114 of an individual stack structure 101, the SWD device 134 of a respective vertical stack 136 of the SWD devices 134 operatively associated with the stack structure 101 may at least partially (e.g., substantially) vertically overlap and be coupled to the LWL structure 114.

The WLSEL region 104 of the microelectronic device 100 further includes an additional stack structure 137 including WLSEL line structures 138 vertically stacked relative to one another. The WLSEL line structures 138 of the additional stack structure 137 may be positioned with a vertical span (e.g., a vertical extent) of the LWL tiers 103 of the stack structures 101, and, hence, may be considered and are also referred to herein as an “in-tier” WLSEL line structures 138. The WLSEL line structures 138 of the additional stack structure 137 vertically overlap (e.g., in the Z-direction) and are operatively associated with the vertical stacks 136 of the SWD devices 134 within the WLSEL region 104, as well as the LWL tiers 103 (and LWL structures 114) of the stack structures 101 within the memory array region 102. The additional stack structure 137 within the WLSEL region 104 may be substantially vertically confined within vertical extents of the stack structures 101, such that the additional stack structure 137 is not substantially vertically offset from the stack structures 101. In some embodiments, the WLSEL line structures 138 of the additional stack structure 137 at least partially (e.g., substantially) individually vertically overlap the LWL structures 114 within LWL tiers 103 of the stack structures 101 located at substantially the same vertical position (e.g., vertical elevation) as one another.

The WLSEL line structures 138 of the additional stack structure 137 may be operatively associated with multiple of the vertical stacks 136 of the SWD devices 134 within the WLSEL region 104. For example, if the WLSEL region 104 includes two (2) vertical stacks 136 of the SWD devices 134, each of the WLSEL line structures 138 of the additional stack structure 137 may be operatively associated with each of the two (2) vertical stacks 136 of the SWD devices 134. An individual WLSEL line structure 138 may vertically overlap and be coupled to an individual SWD device 134 from each of the two (2) vertical stacks 136 of the SWD devices 134. As described in further detail below with reference to FIG. 2A, a channel region of an individual SWD device 134 may be located vertically between (e.g., in the Z-direction) portions of an individual WLSEL line structure 138. Different portions of an individual WLSEL line structure 138 may serve as gates (e.g., gate electrodes) for different SWD devices 134 horizontally (e.g., in the X-direction and in the Y-direction) and vertically (e.g., in the Z-direction) overlapping the WLSEL line structure 138. In some embodiments, a portion of an individual WLSEL line structure 138 substantially surrounds four (4) surfaces (e.g., a top surface, a bottom surface, a first side surface, a second side surface) of a semiconductor structure of an individual SWD device 134 within a horizontal area of a channel region of the SWD device 134. Thus, the SWD device 134 within the WLSEL region 104 of the microelectronic device 100 may be considered to be Gate-All-Around (GAA) SWD devices 134.

The WLSEL line structures 138 of the additional stack structure 137 may individually horizontally extend in the Y-direction, and may at least partially (e.g., substantially) horizontally overlap one another in the X-direction. In some embodiments, horizontal centerlines, in the X-direction, of the WLSEL line structures 138 are substantially horizontally aligned with one another within the WLSEL region 104. The additional stack structure 137 (and, hence, the WLSEL line structures 138 thereof) within the WLSEL region 104 of the microelectronic device 100 is horizontally oriented (e.g., horizontally extend) orthogonal to the stack structures 101 (and, hence, the LWL structures 114 thereof) within the memory array region 102 of the microelectronic device 100.

A quantity of the WLSEL line structures 138 included within the additional stack structure 137 may be selected, at least in-part, based on a quantity of the LWL structures 114 within the LWL tiers 103 of an individual stack structure 101 within the memory array region 102. For example, a quantity of WLSEL line structures 138 included within the additional stack structure 137 may be substantially equal to a quantity of LWL structures 114 included within an individual stack structure 101. For example, as shown in FIG. 1, if an individual stack structure 101 includes three (3) LWL structures 114 (e.g., within three (3) LWL tiers 103), the additional stack structure 137 may include three (3) of the WLSEL line structures 138.

The WLSEL line structures 138 of the additional stack structure 137 may respectively be formed of and include conductive material. In some embodiments, the WLSEL line structures 138 are individually formed of and include one or more of W, Ru, Mo, and TiN.

Still referring to FIG. 1, the GWL region 106 of the microelectronic device 100 includes GWL structures 139 (e.g., GWL pillar structures, vertically oriented GWL structures) respectively vertically extending (e.g., in the Z-direction) across entire vertical spans of the stack structures 101 (and, hence, the vertical stacks of the volatile memory cells 118) with the memory array region 102 and entire vertical spans of the additional stack structures 137 (and, hence, the vertical stacks 136 of the SWD devices 134) within the WLSEL region 104. The GWL structures 139 may respectively be coupled to a vertical stack 136 of the SWD devices 134 within the WLSEL region 104. Each GWL structure 139 vertically extends across (e.g., in the Z-direction), and horizontally neighbors (e.g., in the X-direction), and contacts with the SWD devices 134 of an individual vertical stack 136 of the SWD devices 134. As described in further detail below, in some embodiments, each GWL structure 139 contacts a semiconductor structure of respective ones of the SWD devices 134 of an individual vertical stack 136 of the SWD devices 134.

A quantity of the GWL structures 139 within the GWL region 106 may correspond to a quantity of the vertical stacks 136 of the SWD devices 134 within the WLSEL region 104. Each of the vertical stacks 136 of the SWD devices 134 may include one (1) of the GWL structures 139 operatively associated therewith. An individual GWL structure 139 may horizontally neighbor an individual vertical stack 136 of the SWD devices 134 in the X-direction, may horizontally overlap the vertical stack 136 of the SWD devices 134 in the Y-direction, and may continuously vertically extend across an entire vertical span of the vertical stack 136 of the SWD devices 134 in the Z-direction. Although FIG. 1 illustrates the GWL region 106 of the microelectronic device 100 as including two (2) GWL structures 139 therein (e.g., one for each of two (2) vertical stacks 136 of the SWD devices 134), the disclosure is not so limited. For example, at least partially depending on a quantity of vertical stacks 136 of the SWD devices 134 within the WLSEL region 104, the GWL region 106 may include greater than two (2) of the GWL structures 139, or may include less than two (2) of the GWL structures 139.

The GWL structures 139 may individually be formed of and include conductive material, such as, for example, one or more of at least one metal (e.g., one or more of W, Ti, Ni, Pt, Rh, Ru, Al, Cu, Mo, Ir, Ag, Au), at least one alloy, at least one metal-containing material (e.g., at least one metal nitride, such as one or more of TiN, TaN, WN, and TiAlN); at least one metal silicide; at least one metal carbide; at least one conductive metal oxide (such as one or more of IrOₓ and RuOₓ), alloys thereof, at least one conductively doped semiconductor material (e.g., conductively doped Si, conductively doped Ge, conductively doped SiGe). In some embodiments, the GWL structures 139 are individually formed of and include one or more of W, Ti, Ru, Mo, and TiN.

With continued reference to FIG. 1, the WLIDLE region 108 may include similar features and feature configurations to those previously described herein with reference to WLSEL region 104, but at or proximate opposite horizontal ends in the X-direction of the stack structures 101 within the memory array region 102 as compared to corresponding features of the WLSEL region 104. For example, the WLIDLE region 108 may include vertical stacks 141 of idle SWD devices 140 corresponding to the vertical stacks 136 of SWD devices 134 within the WLSEL region 104. In addition, the WLIDLE region 108 may also include a further stack structure 142 including idle WLSEL line structures 143 corresponding to the additional stack structure 137 including the WLSEL line structures 138 within the WLSEL region 104. Aside from the aforementioned different horizontal positioning and associated interactions at or proximate opposite ends of the stack structures 101, the configurations of the vertical stacks 141 of the idle SWD devices 140 (including of individual idle SWD devices 140 thereof) and the further stack structure 142 (including of the idle WLSEL line structures 143 thereof) may be substantially the same as configurations of the vertical stacks 136 of the SWD devices 134 (including of individual SWD devices 134 thereof) and the additional stack structure 137 (including of the WLSEL line structures 138 thereof), respectively. Accordingly, it will be understood that the description previously provided herein in relation to various features of the WLSEL region 104 may be applied to the aforementioned various corresponding features of the WLIDLE region 108.

Furthermore, the additional GWL region 110 may include similar features and feature configurations to those previously described herein with reference to GWL region 106, but at or proximate the WLIDLE region 108 rather than the WLSEL region 104. For example, the additional GWL region 110 may include additional GWL structures 144 corresponding to the GWL structures 139 within GWL region 106. Aside from the aforementioned different horizontal positioning and associated interactions at or proximate the WLIDLE region 108, the configurations of the additional GWL structures 144 of the additional GWL region 110 may be substantially the same as configurations of the GWL structures 139 within GWL region 106. Accordingly, it will be understood that the description previously provided herein in relation to various features of the GWL region 106 may be applied to the aforementioned various corresponding features of the additional GWL region 110.

Still referring to FIG. 1, the staircase region 112 of the microelectronic device 100 may include at least one staircase structure 146 operatively associated with the additional stack structure 137 of the WLSEL region 104, and at least one additional staircase structure 152 operatively associated with the further stack structure 142 of the WLIDLE region 108. The staircase structure 146 is also referred to herein as a “WLSEL staircase structure.” The additional staircase structure 152 is also referred to herein as a “WLIDLE staircase structure.” As described in further detail below, the staircase structure 146 may be configured to facilitate electrical contact between the WLSEL line structures 138 of the additional stack structure 137 and one or more other devices (e.g., WLSEL generator devices) of the microelectronic device 100. Moreover, the additional staircase structure 152 may be configured to facilitate electrical contact between the idle WLSEL line structures 143 of the additional stack structure 137 and one or more other devices of the microelectronic device 100.

The staircase structure 146 may include steps 148 comprising horizontal ends (e.g., edges) of portions of the WLSEL line structures 138 of the additional stack structure 137 horizontally projecting, in the X-direction, out of the WLSEL region 104 of the microelectronic device 100. The steps 148 of the staircase structure 146 may define contact regions for the WLSEL line structures 138 of the additional stack structure 137. As shown in FIG. 1, the staircase structure 146 may be at least partially positioned within a horizontal span, in the X-direction, of the memory array region 102 of the microelectronic device 100. The staircase structure 146 may substantially linearly horizontally extend in the X-direction, and may be horizontally outward of the vertical stacks of the volatile memory cells 118 (e.g., horizontally outward of one or more conductive plate structures 132 operatively associated with a group of the vertical stacks of the volatile memory cells 118) in the Y-direction. In additional embodiments, the configuration of the staircase structure 146 is modified relative to that shown in FIG. 1. For example, the staircase structure 146 may be substantially positioned within a horizontal span, in the X-direction, of the WLSEL region 104 (e.g., may not horizontally project, in the X-direction in the memory array region 102). In some such embodiments, the staircase structure 146 substantially linearly horizontally extends in the Y-direction rather than the X-direction.

The staircase region 112 further includes WLSEL contact structures 156 positioned within horizontal areas of and physically contacting (e.g., landing on) the steps 148 of the staircase structure 146. An individual WLSEL contact structure 156 may have a lower end in physical contact with an individual step 148 of the staircase structure 146. The WLSEL contact structures 156 may respectively be in electronical contact with the one of the WLSEL line structures 138 (by way of contact with a respective one of the steps 148 of the staircase structure 146 operatively associated with the one of the WLSEL line structures 138), as well as with at least one device vertically offset from (e.g., vertically overlying, vertically underlying) the additional stack structure 137 (and the stack structures 101). The at least one device may be, for example, at least one generator device for the WLSEL line structures 138. The WLSEL contact structures 156 may individually be formed of and include conductive material. In some embodiments, the WLSEL contact structures 156 are individually formed of and include one or more of W, Ru, Mo, TiN.

Still referring to FIG. 1, the additional staircase structure 152 may include additional steps 154 comprising horizontal ends (e.g., edges) of portions of the idle WLSEL line structures 143 of the further stack structure 142 horizontally projecting, in the X-direction, out of the WLIDLE region 108 of the microelectronic device 100. The additional steps 154 of the additional staircase structure 152 may define contact regions for the idle WLSEL line structures 143 of the further stack structure 142. As shown in FIG. 1, the additional staircase structure 152 may be at least partially positioned within the horizontal span, in the X-direction, of the memory array region 102 of the microelectronic device 100. The additional staircase structure 152 may substantially linearly horizontally extend in the X-direction, and may be horizontally outward of the vertical stacks of the volatile memory cells 118 (e.g., horizontally outward of one or more conductive plate structures 132 operatively associated with a group of the vertical stacks of the volatile memory cells 118) in the Y-direction. As shown in FIG. 1, in some embodiments, the additional staircase structure 152 is completely horizontally offset, in the Y-direction, from the staircase structure 146. In additional embodiments, the additional staircase structure 152 at least partially (e.g., substantially) horizontally overlaps the staircase structure 146 in the Y-direction. In further embodiments, the additional staircase structure 152 is substantially positioned within a horizontal span, in the X-direction, of the WLIDLE region 108 (e.g., does not horizontally project, in the X-direction in the memory array region 102). In some such embodiments, the additional staircase structure 152 substantially linearly horizontally extends in the Y-direction rather than the X-direction.

The staircase region 112 further includes idle WLSEL contact structures 157 positioned within horizontal areas of and physically contacting (e.g., landing on) the additional steps 154 of the additional staircase structure 152. An individual idle WLSEL contact structure 157 may have a lower end in physical contact with an individual additional step 154 of the additional staircase structure 152. The idle WLSEL contact structures 157 may respectively be in electronical contact with the one of the idle WLSEL line structures 143 (by way of contact with a respective one of the additional steps 154 of the additional staircase structure 152 operatively associated with the one of the idle WLSEL line structures 143), as well as with at least one device vertically offset from (e.g., vertically overlying, vertically underlying) the further stack structure 142 (and the stack structures 101). The at least one device may, for example, at least one generator device for the idle WLSEL line structures 143. The idle WLSEL contact structures 157 may individually be formed of and include conductive material. In some embodiments, the idle WLSEL contact structures 157 are individually formed of and include one or more of W, Ru, Mo, TiN.

FIG. 2A shows a simplified, partial-cutaway perspective view of a portion A (identified with a dashed box in FIG. 1) of the microelectronic device 100 shown in FIG. 1, in accordance with some embodiments of the disclosure. The portion A encompasses the parts of the memory array region 102, the WLSEL region 104, and the GWL region 106 at or proximate a vertical elevation, in the Z-direction, of a single (e.g., one) LWL tier 103 of the stack structure 101. FIG. 2A depicts a configuration C1 that may be employed within the portion A. FIG. 2A shows, without limitation, some of the access devices 120 (within the memory array region 102) at or proximate the tier 103 of the stack structure 101; the SWD device 134 (within the WLSEL region 104) operatively connected to the LWL structure 114 operatively connected to the some of the access devices 120; and a contact region 172 between the SWD device 134 and the LWL structure 114. While additional features (e.g., structures, materials) of the microelectronic device 100 are described herein below with reference to the portion A of the microelectronic device 100, such additional features may also be formed and included in additional portions of the microelectronic device 100, including additional portions respectively at or proximate a vertical elevation, in the Z-direction, of a different tier 103 of the stack structure 101. FIG. 2B shows a simplified, partial vertical cross-sectional view, in a ZY-plane, of a section B (identified with a dashed line B-B shown in FIG. 1) of the microelectronic device 100 collectively shown in FIGS. 1 and 2A. FIG. 2C shows a simplified, partial-cutaway perspective view of a further portion of the microelectronic device 100 collectively shown in FIGS. 1, 2A, and 2B.

Referring to FIG. 2A, the access devices 120 within the memory array region 102 of the microelectronic device 100 respectively include a semiconductor structure 124 having a first source/drain region 158, a second source/drain region 160, and a channel region 161 horizontally interposed between the first source/drain region 158 and the second source/drain region 160 in the Y-direction. The access devices 120 may respectively further include a portion of the LWL structure 114 overlapping (e.g., horizontally overlapping, vertically overlapping) the channel region 161 of the semiconductor structure 124 thereof, and serving as a gate (e.g., a gate electrode) for the access device 120. In addition, the access devices 120 also respectively include gate dielectric material 162 interposed between the channel region 161 of the semiconductor structure 124 thereof and the portion of the LWL structure 114 serving as a gate for the access device 120.

For an individual access device 120, the first source/drain region 158 and the second source/drain region 160 thereof may comprise portions of the semiconductor structure 124 doped (e.g., impregnated) with one or more conductivity-enhancing species, such as at least one N-type dopant (e.g., one or more of phosphorus, arsenic, antimony, and bismuth) or at least one P-type dopant (e.g., one or more of boron, aluminum, and gallium). In some embodiments, the semiconductor structure 124 is formed of and includes polycrystalline silicon (also referred to herein as “polysilicon”), and the first source/drain region 158 and the second source/drain region 160 respectively comprise N-type doped polycrystalline silicon. In additional embodiments, the semiconductor structure 124 is formed of and includes polycrystalline silicon, and the first source/drain region 158 and the second source/drain region 160 respectively comprise P-type doped polycrystalline silicon. In addition, the channel region 161 of the access device 120 may comprise a portion of the semiconductor structure 124 that is substantially undoped, or that is doped with a different type of conductivity-enhancing species than each of the first source/drain region 158 and the second source/drain region 160 (e.g., if the first source/drain region 158 and the second source/drain region 160 respectively comprise N-type doped polycrystalline silicon, the channel region 161 may comprise P-type doped polycrystalline silicon; or if the first source/drain region 158 and the second source/drain region 160 respectively comprise P-type doped polycrystalline silicon, the channel region 161 may comprise N-type doped polycrystalline silicon). In some embodiments, the first source/drain region 158 of an individual access device 120 is proximate and coupled to a horizontally neighboring (e.g., in the Y-direction) storage node device 122 (FIG. 1) of a volatile memory cell 118 including the access device 120 and the storage node device 122; and the second source/drain region 160 of the access device 120 is proximate and coupled to a horizontally neighboring (e.g., in the Y-direction) conductive pillar structure 116.

As previously discussed herein, an individual access device 120 within the memory array region 102 may have GAA configuration, wherein conductive material of the LWL structure 114 substantially surrounds four (4) surfaces (e.g., a top surface and a bottom surface opposing one another in the Z-direction, and two side surfaces opposing one another in the X-direction) of the semiconductor structure 124 forming the first source/drain region 158, the second source/drain region 160, and the channel region 161 of the access device 120. In addition, as shown in FIG. 2A, a group (e.g., a row) of the access devices 120 at substantially the same vertical elevation as one another in the Z-direction, horizontally offset from one another in the X-direction, and substantially horizontally aligned with one another in the Y-direction may each exhibit a GAA configuration and may share a single (e.g., only) one LWL structure 114 with one another to form the gates thereof.

For an individual access device 120, the gate dielectric material 162 thereof may also substantially surround the four (4) surfaces (e.g., a top surface and a bottom surface opposing one another in the Z-direction, and two side surfaces opposing one another in the X-direction) of the semiconductor structure 124 forming the first source/drain region 158, the second source/drain region 160, and the channel region 161 of the access device 120. The gate dielectric material 162 may be formed of and include insulative material, such as one or more of at least one dielectric oxide material (e.g., SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiment, the gate dielectric material 162 is formed of and includes SiOₓ (e.g., SiO₂).

The access devices 120 within the memory array region 102 of the microelectronic device 100 may individually be considered to be horizontally oriented in the Y-direction since the channel region 161 thereof is horizontally interposed, in the Y-direction, between the first source/drain region 158 thereof and the second source/drain region 160 thereof. The horizontal orientation (e.g., Y-direction orientation) of the access devices 120 may be different than (e.g., orthogonal to) a horizontal orientation of the SWD devices 134 operatively connected thereto by way of the LWL structures 114.

Still referring to FIG. 2A, an individual SWD device 134 (e.g., an ITSWD device) within the WLSEL region 104 of the microelectronic device 100 is configured to facilitate, upon activation thereof (e.g., by way of a threshold voltage (Vₜ) applied to the WLSEL line structure 138 operably connected thereto), desired transmission of a signal from the GWL structure 139 operably connected to the SWD device 134 to the LWL structure 114 operably connected to the SWD device 134 (and, hence, the volatile memory cells 118 operatively connected to the LWL structure 114). The SWD devices 134 may respectively include an additional semiconductor structure 150 having a first source/drain region 164, a second source/drain region 166, and a channel region 168 horizontally interposed between the first source/drain region 158 and the second source/drain region 160 in the X-direction. The SWD devices 134 may respectively further include a portion of the WLSEL line structure 138 overlapping (e.g., horizontally overlapping, vertically overlapping) the channel region 168 of the additional semiconductor structure 150 thereof, and serving as a gate (e.g., a gate electrode) for the SWD device 134. In addition, the SWD devices 134 also respectively include additional gate dielectric material 170 interposed between the channel region 168 of the additional semiconductor structure 150 thereof and the portion of the WLSEL line structure 138 serving as a gate for the SWD device 134.

For an individual SWD device 134, the additional semiconductor structure 150 thereof may vertically overlap the semiconductor structures 124 of the access devices 120 within the memory array region 102 operatively connected to the SWD device 134 by way of one of the LWL structures 114. For example, within a vertical span of an individual LWL tier 103 of the stack structure 101, a vertical position (e.g., in the Z-direction) of the semiconductor structures 124 of the access devices 120 operatively connected to the LWL structure 114 of the LWL tier 103 may be substantially the same as a vertical position of the additional semiconductor structure 150 of the SWD device 134 also operatively connected to the LWL structure 114. In addition, the additional semiconductor structure 150 of the SWD device 134 may be horizontally offset from the semiconductor structures 124 of the access devices 120 in the X-direction, and may at least partially (e.g., only partially) horizontally overlap the semiconductor structures 124 of the access devices 120 in the Y-direction.

The additional semiconductor structure 150 of an individual SWD device 134 within the WLSEL region 104 may have a relatively larger horizontal area than that of the semiconductor structure 124 of a respective one of the access devices 120 within the memory array region 102. For example, as shown in FIG. 2A, the additional semiconductor structure 150 of an individual SWD device 134 within the WLSEL region 104 may have a relatively larger horizontal dimension (e.g., length) in the X-direction than that of the semiconductor structure 124 of an individual access device 120 within the memory array region 102, and may also have a relatively larger horizontal dimension (e.g., width) in the Y-direction than that of the semiconductor structure 124 of the access device 120. In addition, a vertical dimension (e.g., height) in the Z-direction of the additional semiconductor structure 150 of an individual SWD device 134 within the WLSEL region 104 may be substantially equal to or different than (e.g., less than, greater than) that of the semiconductor structure 124 of a respective one of the access devices 120 within the memory array region 102. In some embodiments, the additional semiconductor structure 150 of respective ones of the SWD devices 134 within the WLSEL region 104 has substantially the same vertical dimension as the semiconductor structure 124 of respective ones of the access devices 120 within the memory array region 102.

The additional semiconductor structure 150 of an individual SWD device 134 within the WLSEL region 104 may be formed of and include semiconductor material. A material composition of the additional semiconductor structure 150 of respective ones of the SWD devices 134 may be substantially the same as a material composition of the semiconductor structure 124 of respective ones of the access devices 120, or the material composition of the additional semiconductor structure 150 of respective ones of the SWD devices 134 may be different than the material composition of the semiconductor structure 124 of respective ones of the access devices 120. In some embodiments, the additional semiconductor structures 150 of the SWD devices 134 are respectively formed of and include polysilicon.

Still referring to FIG. 2A, for an individual SWD device 134, the first source/drain region 164 thereof may comprise a portion of the additional semiconductor structure 150 doped (e.g., impregnated) with one or more conductivity-enhancing species, such as at least one N-type dopant (e.g., one or more of phosphorus, arsenic, antimony, and bismuth) or at least one P-type dopant (e.g., one or more of boron, aluminum, and gallium). In some embodiments, the first source/drain region 164 of respective ones of the SWD devices 134 is formed of and includes N-type doped polysilicon. For example, the first source/drain region 164 of respective ones of the SWD devices 134 may formed of and include N+ polysilicon (e.g., polysilicon relatively heavily doped with N-type dopant, such as polysilicon having an N-type dopant concentration greater than or equal to 1.0 ×10¹⁹ N-type dopant atoms per cubic centimeter (cm³)). In additional embodiments, the first source/drain region 164 of respective ones of the SWD devices 134 is formed of and includes P-type doped polysilicon.

The first source/drain region 164 of an individual SWD device 134 may be proximate and coupled to a horizontally neighboring (e.g., in the X-direction) GWL structure 139 of the microelectronic device 100. For example, the first source/drain region 164 of the SWD device 134 may horizontally extend, in the X-direction, from the GWL structure 139 to the channel region 168 of the SWD device 134. In addition, the first source/drain region 164 of the SWD device 134 may substantially continuously extend, in the Y-direction, across an entire horizontal dimension (e.g., width) of the additional semiconductor structure 150 in the Y-direction. In some embodiments, a horizontal dimension (e.g., length) in the X-direction of the first source/drain region 164 of an individual SWD device 134 is substantially uniform (e.g., substantially constant, substantially non-variable) across the entire horizontal dimension (e.g., width) of the additional semiconductor structure 150 (and, hence, the first source/drain region 164) of the SWD device 134 in the Y-direction. The first source/drain region 164 of an individual SWD device 134 may, for example, have a substantially rectangular horizontal cross-sectional shape.

For an individual SWD device 134, the second source/drain region 166 thereof may comprise at least one additional portion of the additional semiconductor structure 150 doped (e.g., impregnated) with one or more conductivity-enhancing species, such as at least one N-type dopant (e.g., one or more of phosphorus, arsenic, antimony, and bismuth) or at least one P-type dopant (e.g., one or more of boron, aluminum, and gallium). A dopant conductivity type of the second source/drain region 166 of the SWD device 134 may be the same as that of the first source/drain region 164 of the SWD device 134. In some embodiments, the second source/drain region 166 of respective ones of the SWD devices 134 is formed of and includes N-type doped polysilicon. For example, the second source/drain region 166 of respective ones of the SWD devices 134 may be formed of and include N+ polysilicon (e.g., polysilicon relatively heavily doped with N-type dopant, such as polysilicon having an N-type dopant concentration greater than or equal to 1.0×10¹⁹ N-type dopant atoms/cm³). In additional embodiments, the second source/drain region 166 of respective ones of the SWD devices 134 is formed of and includes P-type doped polysilicon.

The second source/drain region 166 of an individual SWD device 134 may be proximate and coupled to a horizontally neighboring (e.g., in the X-direction) LWL structure 114 of the microelectronic device 100. For example, the second source/drain region 166 of the SWD device 134 may horizontally extend, in the X-direction, from the LWL structure 114 to the channel region 168 of the SWD device 134.

As shown in FIGS. 2A and 2C, the second source/drain region 166 of an individual SWD device 134 may include a first sub-region 166A and a second sub-region 166B horizontally neighboring the first sub-region 166A in the Y-direction. Some portions of the first sub-region 166A and the second sub-region 166B substantially aligned with one another in the X-direction may be relatively more horizontally offset from one another in the Y-direction than some other portions of the first sub-region 166A and the second sub-region 166B that are also substantially aligned with one another in the X-direction but horizontally offset from the some portions of the first sub-region 166A and the second sub-region 166B in the X-direction. For example, the first sub-region 166A and the second sub-region 166B may converge toward one another in the Y-direction as the first sub-region 166A and the second sub-region 166B progressively get closer, in the X-direction, to the memory array region 102. Correspondingly, the first sub-region 166A and the second sub-region 166B may diverge away from one another in the Y-direction as the first sub-region 166A and the second sub-region 166B progressively get closer, in the X-direction, to the GWL region 106. Portions of the first sub-region 166A and the second sub-region 166B may effectively be merged together in the Y-direction at horizontal positions in the X-direction relatively more proximate to the memory array region 102, but additional portions of the first sub-region 166A and the second sub-region 166B may effectively be spaced apart from one another together in the Y-direction at additional horizontal positions in the X-direction relatively more distal from the memory array region 102. In some embodiments, the first sub-region 166A and the second sub-region 166B of the second source/drain region 166 of an individual SWD device 134 respectively exhibit an at least partially arcuate (e.g., curved) inner horizontal boundary adjacent to the channel region 168 of the SWD device 134. Accordingly, the second source/drain region 166 of the SWD device 134 may exhibit variable (e.g., non-uniform, non-contact) horizontal dimensions (e.g., lengths) in the X-direction across an entire horizontal dimension (e.g., width) of the additional semiconductor structure 150 of the SWD device 134 in the Y-direction.

The second source/drain region 166 of an individual SWD device 134 may partially horizontally overlap, in each of the Y-direction and the X-direction, the LWL structure 114 operatively connected thereto. For example, shown in FIG. 2A, the LWL structure 114 may be at least partially (e.g., substantially) horizontally positioned, in the Y-direction, within a horizontal span, in the Y-direction, of the second sub-region 166B of the second source/drain region 166. In addition, as also shown in FIG. 2A, a portion (e.g., an end portion) of the LWL structure 114 may horizontally overlap, in the X-direction, the second sub-region 166B of the second source/drain region 166. In other embodiments, the second source/drain region 166 of an individual SWD device 134 partially horizontally overlaps the LWL structure 114 operatively connected thereto in the Y-direction, but not in the X-direction. For example, another structure may horizontally intervene between the LWL structure 114 and the second source/drain region 166 of an individual SWD device 134 in the X-direction. A contact region 172 between the second source/drain region 166 of an individual SWD device 134 and the LWL structure 114 operatively connected to the SWD device 134 is described in further detail below.

Referring to FIG. 2A, the channel region 168 of an individual SWD device 134 may comprise a portion of the additional semiconductor structure 150 that is substantially undoped, or that is doped with a different type of conductivity-enhancing species than each of the first source/drain region 164 and the second source/drain region 166 (e.g., if the first source/drain region 164 and the second source/drain region 166 respectively comprise N-type doped polysilicon, the channel region 168 may comprise P-type doped polysilicon; or if the first source/drain region 164 and the second source/drain region 166 respectively comprise P-type doped polysilicon, the channel region 168 may comprise N-type doped polysilicon). In some embodiments, the channel region 168 of respective ones of the SWD devices 134 is formed of and includes substantially undoped polysilicon. In additional embodiments, the channel region 168 of respective ones of the SWD devices 134 is formed of and includes P-type doped polysilicon. In further embodiments, the channel region 168 of respective ones of the SWD devices 134 is formed of and includes N-type doped polysilicon.

The channel region 168 of an individual SWD device 134 may horizontally extend, in the X-direction, from the first source/drain region 164 of the SWD device 134 to the second source/drain region 166 of the SWD device 134. In addition, at least the portion of the channel region 168 that horizontally overlaps, in the X-direction, the WLSEL line structure 138 operatively connected to the SWD device 134 may substantially continuously extend, in the Y-direction, across an entire horizontal dimension (e.g., width) of the additional semiconductor structure 150 in the Y-direction. A horizontal cross-sectional shape of the channel region 168 may be partially defined by horizontal boundaries of the first source/drain region 158 and the second source/drain region 160 horizontally adjacent thereto in the X-direction. For example, as shown in FIG. 2A, the channel region 168 of an individual SWD device 134 may have an irregular horizontal cross-sectional shape affected, in part, by a substantially linear horizontal boundary in the X-direction of the first source/drain region 158 of the SWD device 134 and an at least partially non-linear (e.g., arcuated, curved) horizontal boundary in the X-direction of the second source/drain region 166 of the SWD device 134. The channel region 168 of an individual SWD device 134 may exhibit variable (e.g., non-uniform, non-contact) horizontal dimensions (e.g., lengths) in the X-direction across an entire horizontal dimension (e.g., width) of the additional semiconductor structure 150 of the SWD device 134 in the Y-direction.

As previously discussed herein, an individual SWD device 134 within the WLSEL region 104 may have GAA configuration, wherein conductive material of the WLSEL line structure 138 substantially surrounds four (4) surfaces (e.g., a top surface and a bottom surface opposing one another in the Z-direction, and two side surfaces opposing one another in the Y-direction) of the additional semiconductor structure 150 forming the first source/drain region 164, the second source/drain region 166, and the channel region 168 of the SWD device 134. In addition, as shown collectively by FIGS. 1 and 2B, a group (e.g., a column) of the SWD devices 134 at substantially the same vertical elevation as one another in the Z-direction, horizontally offset from one another in the Y-direction, and substantially horizontally aligned with one another in the X-direction may each exhibit a GAA configuration and may share a single (e.g., only) one WLSEL line structure 138 with one another to form the gates thereof.

For an individual SWD device 134, the portion of the WLSEL line structure 138 forming the gate thereof may vertically overlap the LWL structure 114 operatively connected to the SWD device 134. For example, within a vertical span of an individual LWL tier 103 of the stack structure 101, a vertical position (e.g., in the Z-direction) of the WLSEL line structure 138 forming the gate of an individual SWD device 134 may be substantially the same as a vertical position of the LWL structure 114 operatively connected to the SWD device 134. The WLSEL line structure 138 forming the gate of the SWD device 134 may be horizontally offset, in the X-direction, from the LWL structure 114 operatively connected to the SWD device 134, and may partially horizontally overlap the LWL structure 114 in the Y-direction.

For an individual SWD device 134, the portion of the WLSEL line structure 138 forming the gate thereof may have a horizontal dimension (e.g., length) in the X-direction, referred to herein as a “gate length (L_{g}),” less than a smallest horizontal dimension (e.g., a smallest length) in the X-direction of the channel region 168 of the SWD device 134. In some embodiments, the L_{g} of the portion of the WLSEL line structure 138 forming the gate of the SWD device 134 is within a range of from about 20 nm to about 150 nm, such as from about 20 nm to about 100 nm, from about 40 nm to about 100 nm, from about 60 nm to about 100 nm, from about 70 nm to about 90 nm, or about 85 nm.

For an individual SWD device 134, the portion of the WLSEL line structure 138 forming the gate thereof is completely horizontally offset, in the X-direction, from each of the first source/drain region 164 and the second source/drain region 166 of the SWD device 134. Put another way, the portion of the WLSEL line structure 138 forming the gate of the SWD device 134 may be substantially confined, in the X-direction, within a horizontal span of the channel region 168 of the SWD device 134 in the X-direction. The portion of the WLSEL line structure 138 forming the gate of the SWD device 134 may be substantially equidistantly horizontally offset, in the X-direction, from portions of the first source/drain region 164 and the second source/drain region 166 closest thereto in the X-direction; or may be horizontally positioned, in the X-direction, relatively closer to one of the first source/drain region 164 and the second source/drain region 166 than the other of the first source/drain region 164 and the second source/drain region 166. The portion of the WLSEL line structure 138 forming the gate of the SWD device 134 may be horizontally offset, in the X-direction, from a portion of the second source/drain region 166 of the SWD device 134 horizontally closest thereto by a minimum horizontal distance in the X-direction, referred to herein as a “contact-to-gate (CTG) distance,” greater than or equal to about 10 nm. In some embodiments, the CTG distance is within a range of from about 10 nm to about 40 nm, such as from about 10 nm to about 100 nm, such as from about 10 nm to about 80 nm, from about 10 nm to about 60 nm, from about 10 nm to about 40 nm, from about 20 nm to about 40 nm, or about 30 nm.

For an individual SWD device 134, the additional gate dielectric material 170 thereof may also substantially surround the four (4) surfaces (e.g., a top surface and a bottom surface opposing one another in the Z-direction, and two side surfaces opposing one another in the Y-direction) of the additional semiconductor structure 150 forming the first source/drain region 164, the second source/drain region 166, and the channel region 168 of the SWD device 134. The additional gate dielectric material 170 may be formed of and include insulative material, such as one or more of at least one dielectric oxide material (e.g., SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). A material composition of the additional gate dielectric material 170 of respective ones of the SWD devices 134 may be substantially the same as a material composition of the gate dielectric material 162 of respective ones of the access devices 120 within the memory array region 102, or the material composition of the additional gate dielectric material 170 of respective ones of the SWD devices 134 may be different than the material composition of the gate dielectric material 162 of respective ones of the access devices 120. In some embodiment, the additional gate dielectric material 170 is formed of and includes SiOₓ (e.g., SiO₂).

For an individual SWD device 134, the additional gate dielectric material 170 thereof may vertically overlap the gate dielectric material 162 of the access devices 120 within the memory array region 102 operatively connected to the SWD device 134 by way of one of the LWL structures 114. For example, within a vertical span of an individual LWL tier 103 of the stack structure 101, a vertical position (e.g., in the Z-direction) of the gate dielectric material 162 of the access devices 120 operatively connected to the LWL structure 114 of the LWL tier 103 may be substantially the same as a vertical position of the additional gate dielectric material 170 of the SWD device 134 also operatively connected to the LWL structure 114.

The SWD devices 134 within the WLSEL region 104 of the microelectronic device 100 may individually be considered to be horizontally oriented in the X-direction since the channel region 168 thereof is horizontally interposed, in the X-direction, between the first source/drain region 164 thereof and the second source/drain region 166 thereof. As previously described herein, the horizontal orientation (e.g., X-direction orientation) of the SWD devices 134 may be different than (e.g., orthogonal to) a horizontal orientation (e.g., Y-direction orientation) of the access devices 120 operatively connected thereto by way of the LWL structures 114.

Still referencing FIG. 2A, an individual SWD device 134 may contact (e.g., electrically contact, physically contact) an individual LWL structure 114 operatively associated with the SWD device 134 at a contact region 172 (e.g., an interface region, a junction region). In some embodiments, the contact region 172 includes one or more locations wherein opposing surfaces 174 (e.g., opposing bottom and top surfaces, opposing side surfaces) of the LWL structure 114 and the second source/drain region 166 of the additional semiconductor structure 150 of the SWD device 134 directly physically contact one another. For example, as shown in FIG. 2A, portions of the LWL structure 114 may extend (e.g., vertically extend, horizontally extend) over and physically contact a portion (e.g., part of the second sub-region 166B) of the second source/drain region 166 of the SWD device 134. In some embodiments, at or within the contact region 172, the LWL structure 114 continuously extends over and physically contacts portions of a top surface, a side surface, and a bottom surface of the second source/drain region 166 of the additional semiconductor structure 150 of the SWD device 134. In additional embodiments, at or within the contact region 172, the LWL structure 114 extends over and physically contacts portions of less than three (3) surfaces of the second source/drain region 166 of the additional semiconductor structure 150 of the SWD device 134, such as only two (2) of the surfaces (e.g., the top surface and the side surface; the bottom surface and the side surface; or the top surface and the bottom surface) or only one (1) of the surfaces (e.g., only one of the top surface, the bottom surface, and the side surface). In further embodiments, at or within the contact region 172, at least one material (e.g., one or more of at least one semiconductor material and at least one conductive material) may be interposed between (e.g., extend from and between) the LWL structure 114 and the second source/drain region 166 of the additional semiconductor structure 150 of the SWD device 134.

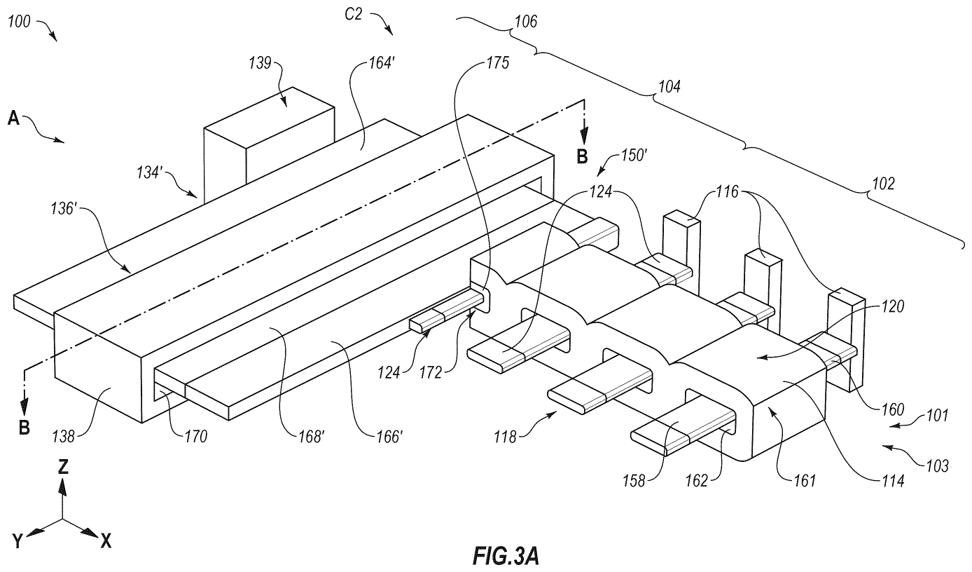

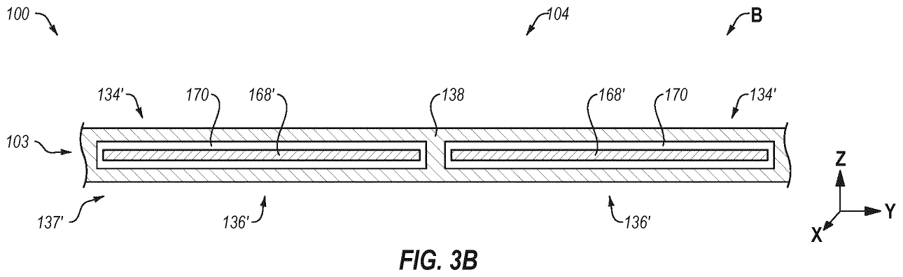

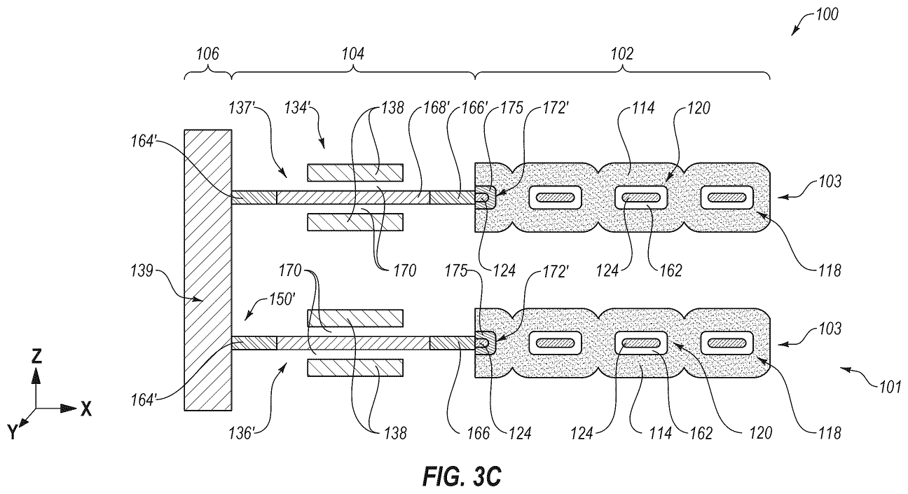

Briefly referring again to FIG. 1, in accordance with additional embodiments of the disclosure, the microelectronic device 100 may be formed to exhibit different configurations of one or more features thereof than those previously described herein with collective reference to FIGS. 1 and 2A through 2C. FIG. 3A shows a simplified, partial-cutaway perspective view of the portion A (identified with a dashed box in FIG. 1) of the microelectronic device 100 shown in FIG. 1, in accordance with some additional embodiments of the disclosure. The portion A still encompasses the parts of the memory array region 102, the WLSEL region 104, and the GWL region 106 at or proximate a vertical elevation, in the Z-direction, of a single (e.g., one) tier 103 of the stack structure 101. However, FIG. 3A depicts an additional configuration C2, different in some ways than the configuration C1 previously described with reference to FIG. 2A, that may be employed within the portion A. While additional features (e.g., structures, materials) of the microelectronic device 100 are described herein below with reference to the portion A of the microelectronic device 100, such additional features may also be formed and included in additional portions of the microelectronic device 100, including additional portions respectively at or proximate a vertical elevation, in the Z-direction, of a different tier 103 of the stack structure 101. FIG. 3B shows a simplified, partial vertical cross-sectional view, in a ZY-plane, of a section B (identified with a dashed line B-B shown in FIG. 1) of the microelectronic device 100 collectively shown in FIGS. 1 and 3A. FIG. 3C shows simplified, partial vertical cross-sectional view, in a ZX-plane, of an additional portion of the microelectronic device 100 collectively shown in FIGS. 1, 3A, and 3B.

To avoid repetition, not all features shown in FIGS. 3A through 3C are described in detail herein. Features common between FIGS. 1, 2A through 2C, and 3A through 3C retain the same numerical designation. In addition, unless described otherwise below, a feature designated by a reference numeral that is a prime (′) of a reference numeral of a previously described feature will be understood to be functionally similar to and to have some configurational similarities to the previously described feature, but to also have one or more differences relative to a configuration previously described with reference to one or more of FIGS. 1 and 2A through 2C. By way of non-limiting example, in FIGS. 3A through 3C, an individual SWD device 134′ (e.g., an individual ITSWD device) may be functionally similar to and may have some configurational similarities to an individual SWD device 134 previously described with reference to one or more of FIGS. 1 and 2A through 2C, but may also have some differences (e.g., structural differences, such as size differences and/or shape differences) as compared the SWD device 134 previously described with reference to one or more of FIGS. 1 and 2A through 2C.

Referring to FIG. 3A, for the additional configuration C2, an individual SWD device 134′ (e.g., ITSWD device) within the WLSEL region 104 of the microelectronic device 100 may have some structural differences to features thereof as compared to an individual SWD device 134 for the configuration C1 previously described herein with reference to FIG. 2A. For example, as described in further detail below, the SWD device 134′ may exhibit some differences to the additional semiconductor structure 150′ thereof (relative to the additional semiconductor structure 150 (FIG. 2A)), including differences to the first source/drain region 164′ (relative to the first source/drain region 164 (FIG. 2A)), the second source/drain region 166′ (relative to the second source/drain region 166 (FIG. 2A)), and the channel region 168′ (relative to the channel region 168 (FIG. 2A)). In addition, as described in further detail below, the contact region 172′ between the second source/drain region 166′ of an individual SWD device 134′ and the LWL structure 114 operatively connected to the SWD device 134′ may exhibit some differences as compared to the contact region 172 for the configuration C1 previously described herein with reference to FIG. 2A.

As shown in FIG. 3A, the additional semiconductor structure 150′ of an individual SWD device 134′ within the WLSEL region 104 may have a relatively reduced horizontal dimension (e.g., length) in the X-direction than that of the additional semiconductor structure 150 (FIG. 2A) of an individual SWD device 134 (FIG. 2A) for the configuration C1 (FIG. 2A) previously described herein. The relatively reduced horizontal dimension, in the X-direction, of the additional semiconductor structure 150′ results, in part, from changes to the second source/drain region 166′ thereof relative to the second source/drain region 166 (FIG. 2A), as described in further detail below. However, the additional semiconductor structure 150′ of the SWD device 134′ still has a larger horizontal area than that of the semiconductor structure 124 of a respective one of the access devices 120 within the memory array region 102. For example, as shown in FIG. 2A, the additional semiconductor structure 150′ of an individual SWD device 134′ within the WLSEL region 104 may have a relatively larger horizontal dimension (e.g., length) in the X-direction than that of the semiconductor structure 124 of an individual access device 120 within the memory array region 102, and may also have relatively larger horizontal dimension (e.g., width) in the Y-direction than that of the semiconductor structure 124 of the access device 120. In addition, a vertical dimension (e.g., height) in the Z-direction of the additional semiconductor structure 150′ of an individual SWD device 134′ within the WLSEL region 104 may be substantially equal to or different than (e.g., less than, greater than) that of the semiconductor structure 124 of a respective one of the access devices 120 within the memory array region 102. In some embodiments, the additional semiconductor structure 150′ of respective ones of the SWD devices 134′ within the WLSEL region 104 has substantially the same vertical dimension as the semiconductor structure 124 of respective ones of the access devices 120 within the memory array region 102.

For an individual SWD device 134′, the second source/drain region 166′ of the additional semiconductor structure 150′ may substantially continuously extend, in the Y-direction, across an entire horizontal dimension (e.g., width) of the additional semiconductor structure 150′ in the Y-direction, and may also have a substantially uniform (e.g., substantially constant, substantially non-variable) horizontal dimension (e.g., length) in the X-direction across the entire horizontal dimension (e.g., width) of the additional semiconductor structure 150′ (and, hence, the second source/drain region 166′) of the SWD device 134′ in the Y-direction. The second source/drain region 166′ of an individual SWD device 134′ may, for example, have a substantially rectangular horizontal cross-sectional shape. In some embodiments, a horizontal cross-sectional area of the second source/drain region 166′ of an individual SWD device 134′ is relatively smaller than that of the second source/drain region 166 (FIG. 2A) of an individual SWD device 134 (FIG. 2A) for the configuration C1 (FIG. 2A) previously described herein. The horizontal dimension (e.g., length), in the X-direction, of the second source/drain region 166′ may, for example, be relatively smaller than that of the second source/drain region 166 (FIG. 2A).

The structural configuration of the second source/drain region 166′ of the additional semiconductor structure 150′ influences a structural configuration of one or more other regions of the additional semiconductor structure 150′, such as at least the channel region 168′. For example, for an individual SWD device 134′, the channel region 168′ of the additional semiconductor structure 150′ may substantially continuously extend, in the Y-direction, across an entire horizontal dimension (e.g., width) of the additional semiconductor structure 150′ in the Y-direction, and may have a substantially uniform (e.g., substantially constant, substantially non-variable) horizontal dimension (e.g., length) in the X-direction across the entire horizontal dimension (e.g., width) of the additional semiconductor structure 150′ (and, hence, the channel region 168′) of the SWD device 134′ in the Y-direction. The channel region 168′ of an individual SWD device 134′ may, for example, have a substantially rectangular horizontal cross-sectional shape. In some embodiments, a horizontal cross-sectional area of the channel region 168′ of an individual SWD device 134′ is relatively smaller than that of the channel region 168 (FIG. 2A) of an individual SWD device 134 (FIG. 2A) for the configuration C1 (FIG. 2A) previously described herein. The horizontal dimension (e.g., length), in the X-direction, of the channel region 168′ may, for example, be relatively smaller than a maximum horizontal dimension, in the X-direction, of the channel region 168 (FIG. 2A).

As shown in FIGS. 3A and 3B, for respective ones of the SWD devices 134′, configurations of the additional gate dielectric material 170 of the SWD device 134′ and the portion of the WLSEL line structure 138 forming the gate of the SWD device 134′ may be substantially the same as those previously described with reference to FIGS. 2A through 2C. The portion of the WLSEL line structure 138 forming the gate of an individual SWD device 134′, may have a gate length (L_{g}) less than the horizontal dimension (e.g., length) in the X-direction of the channel region 168′ of the SWD device 134′ (e.g., a L_{g} within a range of from about 60 nm to about 100 nm, such as from about 70 nm to about 90 nm, or about 85 nm). In addition, a contact-to-gate (CTG) distance between the portion of the WLSEL line structure 138 forming the gate of the SWD device 134′ and the second source/drain region 166′ of the SWD device 134′ may be greater than or equal to about 10 nm (e.g., within a range of from about 10 nm to about 40 nm, such as from about 20 nm to about 40 nm, or about 30 nm).

Referring to FIG. 3A, an individual SWD device 134′ may contact (e.g., electrically contact) an individual LWL structure 114 operatively associated with the SWD device 134′ at a contact region 172′ (e.g., an interface region, a junction region). The contact region 172′ exhibits a different configuration than that of the contact region 172 (FIG. 2A) previously described herein. For example, at or within the contact region 172′, the second source/drain region 166′ of the additional semiconductor structure 150′ of an individual SWD device 134′ may contact (e.g., electrically contact, physically contact) one of the semiconductor structures 124 of the memory array region 102 not employed with an access device 120 of the memory array region 102. In addition, in place of the gate dielectric material 162 that would otherwise be interposed between the semiconductor structures 124 of the access devices 120 and the LWL structure 114, a non-insulative material 175 (e.g., a non-insulative interfacial material) may be interposed between the one of the semiconductor structures 124 contacting the second source/drain region 166′ of the SWD device 134′ and the LWL structure 114.

As shown in FIGS. 3A and 3C, at or within an individual contact region 172′, a side surface of at least a portion of a semiconductor structure 124 not employed within an access device 120 of one of the volatile memory cells 118 may directly physically contact an opposing side surface of the second source/drain region 166′ of the additional semiconductor structure 150′ of an individual SWD device 134′. A configuration of the semiconductor structure 124 directly physically contacting the second source/drain region 166′ of the SWD device 134′ may be substantially the same as or different than a configuration of the semiconductor structures 124 employed within the access devices 120 of the volatile memory cells 118 within the memory array region 102. In some embodiments, the semiconductor structure 124 directly physically contacting the second source/drain region 166′ of the SWD device 134′ has a relatively smaller horizontal dimension (e.g., length) in the X-direction than respective ones of the semiconductor structures 124 employed within the access devices 120 of the volatile memory cells 118. Material of an initial semiconductor structure similar to respective ones of the semiconductor structures 124 employed within respective ones of the access devices 120 may, for example, have been removed to form the semiconductor structure 124 directly physically contacting the second source/drain region 166′ of the SWD device 134′.

At or within an individual contact region 172′, the non-insulative material 175 extends from one or more surfaces (e.g., a top surface, another side surface, a bottom surface) of the semiconductor structure 124 contacting the second source/drain region 166′ of an individual SWD device 134′ to one or more opposing surfaces of the LWL structure 114. For example, as shown in FIGS. 3A and 3C, portions of the non-insulative material 175 may extend (e.g., vertically extend, horizontally extend) over and physically contact a portion of the semiconductor structure 124 and may also extend (e.g., vertically extend, horizontally extend) over and physically contact a portion of the LWL structure 114. In some embodiments, at or within the contact region 172′, the non-insulative material 175 continuously extends over and physically contacts portions of a top surface, a side surface, and a bottom surface of the semiconductor structure 124, as well as surfaces of the LWL structure 114 opposing the aforementioned surfaces of the semiconductor structure 124. In additional embodiments, at or within the contact region 172′, the non-insulative material 175 extends over and physically contacts portions of less than three (3) surfaces of the semiconductor structure 124, such as only two (2) of the surfaces (e.g., the top surface and the side surface; the bottom surface and the side surface; or the top surface and the bottom surface) or only one (1) of the surfaces (e.g., only one of the top surface, the bottom surface, and the side surface).

The non-insulative material 175 may be formed to include one or more of at least one conductive material (e.g., one or more of at least one metal, at least one alloy, at least one metal nitride, at least one metal silicide; at least one metal carbide; at least one conductive metal oxide, at least one conductively doped semiconductor material) and at least one semiconductor material. In some embodiments, the non-insulative material 175 is formed of includes one or more of W, Ti, Ni, Pt, Rh, Ru, Al, Cu, Mo, Ir, Ag, Au, and Si.

Referring to FIG. 3C, for an individual vertical stack 137′ of the SWD devices 136′ within the WLSEL region 104, at least some (e.g., all) of the SWD devices 136′ vertically offset from one another in the Z-direction may substantially horizontally overlap one another in each of the X-direction and the Y-direction. For example, a horizontal centerline, in the X-direction, of a first of the SWD devices 136′ of the vertical stack 137′ may be substantially aligned with a horizontal centerline, in the X-direction, of a second of the SWD devices 136′ of the vertical stack 137′ vertically neighboring the first of the SWD devices 136′; and an additional horizontal centerline, in the Y-direction, of the first of the SWD devices 136′ of the vertical stack 137′ may be substantially aligned with an additional horizontal centerline, in the Y-direction, of the second of the SWD devices 136′ of the vertical stack 137′ vertically neighboring the first of the SWD devices 136′.

Thus, in accordance with embodiments of the disclosure, a microelectronic device includes local word line (LWL) structures, memory cells, sub-word line driver (SWD) devices, and a global word line (GWL) structure. The LWL structures are vertically stacked relative to one another. The memory cells are vertically stacked relative to one another within a vertical span of the LWL structures, and are operatively connected to different ones of the LWL structures than one another. The SWD devices are vertically stacked relative to one another within the vertical span of the LWL structures, and are individually operatively connected to a respective one of the LWL structures. The GWL structure continuously vertically extending across and is operatively connected to the SWD devices.

Furthermore, in accordance with embodiments of the disclosure, a microelectronic device includes a memory array region, a global word line (GWL) region, and a word line select (WLSEL) region. The memory array region includes stack structures horizontally extending in parallel in a first direction and separated from one another in a second direction orthogonal to the first direction. The stack structures individually include local word line (LWL) structures vertically stacked relative to one another. The GWL region includes GWL structures vertically extending across an entire vertical span of the stack structures of the memory array region. The WLSEL region is horizontally interposed between the memory array region and the GWL region in the first direction. The WLSEL region includes vertical stacks of sub-word line driver (SWD) devices individually coupled to, vertically overlapping, and horizontally extending between one of GWL structures of the GWL region and the LWL structures of one of the stack structures of the memory array region.

Moreover, in accordance with embodiments of the disclosure, a memory device includes a stack structure, vertical stacks of volatile memory cells, a global word line (GWL) structure, and a vertical stack of sub-word line driver (SWD) devices. The stack structure includes local word line (LWL) structures vertically stacked relative to one another and substantially linearly horizontally extending in a first direction. The vertical stacks of volatile memory cells are within a vertical extent of and are individually operatively connected to the LWL structures of the stack structure. The GWL structure continuously vertically extends across all of the LWL structures of the stack structure. The GWL structure horizontally overlaps the stack structure in a second direction perpendicular to the first direction. The vertical stack of SWD devices is horizontally interposed between the GWL structure and the stack structure in the first direction and horizontally overlaps the GWL structure and the stack structure in the second direction. The vertical stack of SWD devices includes SWD devices at vertical elevations of the LWL structures of the stack structure and individually coupled to the GWL structure and a respective one of the LWL structures.

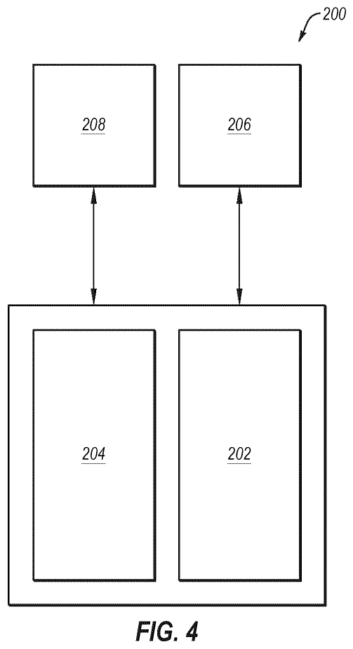

FIG. 4 is a block diagram of an electronic system 200, in accordance with embodiments of the disclosure. The electronic system 200 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 200 includes at least one memory device 202. The memory device 202 may include, for example, an embodiment of a microelectronic device previously described herein (e.g., the microelectronic device 100 previously described with collective reference to FIGS. 1 and 2A through 2C; the microelectronic device 100 previously described with collective reference to FIGS. 1 and 3A through 3C).

The electronic system 200 may further include at least one electronic signal processor device 204 (often referred to as a “microprocessor”). The electronic signal processor device 204 may, optionally, include an embodiment of a microelectronic device previously described herein (e.g., the microelectronic device 100 previously described with collective reference to FIGS. 1 and 2A through 2C; the microelectronic device 100 previously described with collective reference to FIGS. 1 and 3A through 3C). While the memory device 202 and the electronic signal processor device 204 are depicted as two (2) separate devices in FIG. 4, in additional embodiments, a single (e.g., only one) memory/processor device having the functionalities of the memory device 202 and the electronic signal processor device 204 is included in the electronic system 200. In such embodiments, the memory/processor device include, for example, an embodiment of a microelectronic device previously described herein (e.g., the microelectronic device 100 previously described with collective reference to FIGS. 1 and 2A through 2C; the microelectronic device 100 previously described with collective reference to FIGS. 1 and 3A through 3C).

The electronic system 200 may further include one or more input devices 206 for inputting information into the electronic system 200 by a user, such as, for example, a mouse or other pointing device, a keyboard, a touchpad, a button, or a control panel. The electronic system 200 may further include one or more output devices 208 for outputting information (e.g., visual or audio output) to a user such as, for example, one or more of a monitor, a display, a printer, an audio output jack, and a speaker. In some embodiments, the input device 206 and the output device 208 comprise a single touchscreen device that can be used both to input information to the electronic system 200 and to output visual information to a user. The input device 206 and the output device 208 may communicate electrically with one or more of the memory device 202 and the electronic signal processor device 204.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalents. For example, elements and features disclosed in relation to one embodiment of the disclosure may be combined with elements and features disclosed in relation to other embodiments of the disclosure.

What is claimed is:

1. A microelectronic device, comprising:
local word line (LWL) structures vertically stacked relative to one another;
memory cells vertically stacked relative to one another within a vertical span of the LWL structures, the memory cells operatively connected to different ones of the LWL structures than one another;
sub-word line driver (SWD) devices vertically stacked relative to one another within the vertical span of the LWL structures, the SWD devices individually operatively connected to a respective one of the LWL structures; and
a global word line (GWL) structure continuously vertically extending across and operatively connected to the SWD devices.

2. The microelectronic device of claim 1, wherein the memory cells comprise volatile memory cells respectively comprising:
an access device horizontally oriented in a first direction; and
a storage node structure horizontally neighboring and coupled to the access device.

3. The microelectronic device of claim 2, wherein the SWD devices are respectively horizontally oriented in a second direction orthogonal to the first direction.

4. The microelectronic device of claim 3, wherein the SWD devices respectively comprise:
a first source/drain region;
a second source/drain region;
a channel region horizontally interposed between the first source/drain region and the second source/drain region in the second direction;
a gate comprising horizontally overlapping the channel region in the second direction; and
a gate dielectric material interposed between the gate and the channel region.

5. The microelectronic device of claim 4, wherein the SWD devices respectively have a gate-all-around (GAA) configuration such that the gate thereof substantially continuously extends around a top boundary, a bottom boundary, and two opposing side boundaries of the channel region thereof.

6. The microelectronic device of claim 4, wherein each of the LWL structures vertically overlaps and is coupled to:
the second source/drain region of a respective one of the SWD devices; and
the access device of a respective one of the volatile memory cells.

7. The microelectronic device of claim 4, wherein each of the LWL structures vertically overlaps and directly physically contacts the second source/drain region of a respective one of the SWD devices.

8. The microelectronic device of claim 4, wherein a non-insulative interfacial material extends between and electrically connects each of the LWL structures to the second source/drain region of a respective one of the SWD devices.

9. A microelectronic device, comprising:
a memory array region comprising stack structures horizontally extending in parallel in a first direction and separated from one another in a second direction orthogonal to the first direction, the stack structures individually comprising local word line (LWL) structures vertically stacked relative to one another;
a global word line (GWL) region comprising GWL structures vertically extending across an entire vertical span of the stack structures of the memory array region; and
a word line select (WLSEL) region horizontally interposed between the memory array region and the GWL region in the first direction, the WLSEL region comprising vertical stacks of sub-word line driver (SWD) devices individually coupled to, vertically overlapping, and horizontally extending between one of GWL structures of the GWL region and the LWL structures of one of the stack structures of the memory array region.

10. The microelectronic device of claim 9, wherein the memory array region further comprises vertical stacks of volatile memory cells vertically overlapping the stack structures, each of the vertical stacks of volatile memory cells horizontally neighboring a respective one of the stack structures in the second direction and comprising:
a vertical stack of access devices, each of the access devices oriented in the second direction and having a gate comprising a portion of one of the LWL structures of the respective one of the stack structures of the memory array region; and
a vertical stack of storage node devices coupled to and horizontally neighboring the vertical stack of access devices.

11. The microelectronic device of claim 10, wherein respective ones of the SWD devices of respective ones of the vertical stacks of SWD devices are oriented in the first direction.

12. The microelectronic device of claim 9, wherein the WLSEL region further comprises an additional stack structure horizontally extending in the second direction and comprising WLSEL line structures vertically overlapping and coupled to the vertical stacks of SWD devices.

13. The microelectronic device of claim 12, wherein portions of respective ones of the WLSEL line structures of the additional stack structure form gates for respective ones of the SWD devices of respective ones of the vertical stacks of SWD devices.

14. The microelectronic device of claim 13, wherein the respective ones of the SWD devices of the respective ones of the vertical stacks of SWD devices individually have a gate-all-around (GAA) configuration.

15. The microelectronic device of claim 9, wherein respective ones of the SWD devices of respective ones of the vertical stacks of SWD devices individually comprise:
a first source/drain region;
a second source/drain region;
a channel region horizontally extending, in the first direction, from the first source/drain region to the second source/drain region;
a gate confined within a horizontal extent of the channel region in the first direction and comprising a portion of a WLSEL line structure, the WLSEL line structure horizontally extending in the second direction; and
gate dielectric material interposed between the gate and the channel region.

16. The microelectronic device of claim 15, wherein the respective ones of the SWD devices of the respective ones of the vertical stacks of SWD devices individually have a gate length, in the first direction, within a range of from about 60 nm to about 100 nm.

17. The microelectronic device of claim 15, wherein, for the respective ones of the SWD devices of the respective ones of the vertical stacks of SWD devices, the gate thereof is horizontally offset from the second source/drain region therein by a distance within a range of from about 10 nm to about 40 nm.

18. A memory device, comprising:
a stack structure comprising local word line (LWL) structures vertically stacked relative to one another and substantially linearly horizontally extending in a first direction;
vertical stacks of volatile memory cells within a vertical extent of and individually operatively connected to the LWL structures of the stack structure;
a global word line (GWL) structure continuously vertically extending across all of the LWL structures of the stack structure, the GWL structure horizontally overlapping the stack structure in a second direction perpendicular to the first direction; and
a vertical stack of sub-word line driver (SWD) devices horizontally interposed between the GWL structure and the stack structure in the first direction and horizontally overlapping the GWL structure and the stack structure in the second direction, the vertical stack of SWD devices comprising SWD devices at vertical elevations of the LWL structures of the stack structure and individually coupled to the GWL structure and a respective one of the LWL structures.

19. The memory device of claim 18, wherein the vertical stacks of volatile memory cells comprise vertical stacks of dynamic random-access memory (DRAM) cells.

20. The memory device of claim 18, further comprising an additional stack structure comprising word line select (WLSEL) line structures vertically stacked relative to one another substantially linearly horizontally extending in the second direction, portions of the WLSEL line structures of the additional stack structure forming gates for the SWD devices of the vertical stack of SWD devices.
